(19) United States
(12) Patent Application Publication
(10) Pub. No.: US 2026/0271797 A1
(43) Pub. Date: Sep. 10, 2026

(54) HEAT TRANSFER STRUCTURES FOR SEMICONDUCTOR APPARATUSES

(71) Applicant: Micron Technology, Inc., Boise, ID (US)

(72) Inventors: Bharat Bhushan, Boise, ID (US); Amy Rae Griffin, Boise, ID (US); Keizo Kawakita, Hiroshima (JP); Akshay N. Singh, Boise, ID (US)

(21) Appl. No.: 19/540,196

(22) Filed: Feb. 13, 2026

Related U.S. Application Data
(60) Provisional application No. 63/768,767, filed on Mar. 7, 2025.

(51) Int. Cl. H10W 90/20; H10W 20/00; H10W 90/00

(52) U.S. Cl. CPC H10W 90/297; H10W 20/083; H10W 90/734

(57) ABSTRACT

Methods, systems, and devices for heat transfer structures for semiconductor apparatuses are described. A semiconductor apparatus may include thermal dissipation structures within or between semiconductor components, including a dielectric material with a relatively high thermal conductivity, a conductive material, or both. In some examples, an isolation layer may be formed between interconnection layers and may include portions of a dielectric material with a relatively high thermal conductivity, or one or more portions of a conductive material electrically isolated from one or more adjacent interconnection layers, or a combination thereof. Additionally, or alternatively, one or more portions of a dielectric material with a relatively high thermal conductivity may be formed on a backside of a semiconductor substrate. In some cases, a dielectric material on the backside of a semiconductor substrate may electrically isolate the substrate from one or more bonding pads.

### CROSS REFERENCE

The present Application for Patent claims priority to U.S. Patent Application No. 63/768,767 by Bhushan et al., entitled “HEAT TRANSFER STRUCTURES FOR SEMICONDUCTOR APPARATUSES,” filed Mar. 07, 2025, which is assigned to the assignee hereof, and which is expressly incorporated by reference in its entirety herein.

### TECHNICAL FIELD

The following relates to one or more semiconductor systems, including heat transfer structures for semiconductor apparatuses.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports heat transfer structures for semiconductor apparatuses in accordance with examples as disclosed herein.

FIG. 2 shows an example of a system that supports heat transfer structures for semiconductor apparatuses in accordance with examples as disclosed herein.

FIGS. 3 through 6 show cross sections of semiconductor components that support heat transfer structures for semiconductor apparatuses in accordance with examples as disclosed herein.

FIGS. 7 through 9 show flowcharts illustrating methods that support heat transfer structures for semiconductor apparatuses in accordance with examples as disclosed herein.

### DETAILED DESCRIPTION

Some semiconductor systems (e.g., memory systems, processor systems, systems having a combination of memory and processing) may include a stack of semiconductor components (e.g., semiconductor dies), which may include one or more memory dies (e.g., memory dies, array dies, memory array dies) or one or more stacks of memory dies that are stacked with a logic die that is operable to access a set of memory arrays distributed across the one or more memory dies. Such a stacked architecture may be implemented as part of a high bandwidth memory (HBM) system or a coupled dynamic random access memory (DRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

A semiconductor component in a semiconductor system (e.g., an HBM system, a 3D stacked memory system, or other system) may include a substrate (e.g., a semiconductor substrate), and circuitry formed at least in part from a doped portion of the substrate (e.g., a front side of the substrate). Such a semiconductor component may also include conductive lines (e.g., access lines, conductive traces) in one or more interconnection layers (e.g., front-end-of-line (FEOL) layers, back end of line (BEOL) layers) over the substrate, which may interconnect the circuitry of the semiconductor component, circuitry of other semiconductor components, or both. Stacks of interconnection layers, and isolation layers therebetween, may decrease an effective thermal conductivity (e.g., increase an effective thermal resistance, reduce heat dissipation, along a thickness direction) of a semiconductor system, which may increase an operating temperature of the semiconductor system. For example, a semiconductor system may overheat as a result of the lower effective thermal conductivity, which may impede operations or cause damage to one or more components. In some examples, components of the semiconductor system may need to be separated (e.g., spread out) to reduce heat generation per volume, which may reduce spatial efficiency and operational capacity of the semiconductor system.

In accordance with aspects described herein, a semiconductor apparatus may include thermal dissipation structures within or between semiconductor components to increase an effective thermal conductivity and reduce an operating temperature of the semiconductor apparatus. The thermal dissipation structures may include an electrically insulating material with a relatively high thermal conductivity (e.g., aluminum nitride (AlN)) or a conductive material (e.g., copper) to increase an effective thermal conductivity of the semiconductor apparatus. In some examples, an isolation layer (e.g., an interconnection layer that provides isolation or electrical separation between two or more conductive lines) may be formed between two interconnection layers and may include portions of an electrically insulating material with a relatively high thermal conductivity (e.g., higher than another dielectric material of the isolation layer). Additionally, or alternatively, an isolation layer may include one or more portions of a conductive material, and a dielectric layer may separate (e.g., electrically isolate) a portion of the conductive material in the isolation layer from a conductive line in one or more adjacent interconnection layers. Additionally, or alternatively, one or more portions (e.g., one or more pads, a layer) of an electrically insulating material with a relatively high thermal conductivity may be formed on an opposite side (e.g., a backside) of a substrate from the circuitry. In some cases, such portions of the electrically insulating material may separate a semiconductor substrate from one or more bonding pads. As a result of the relatively higher thermal conductivity of the conductive material and the electrically insulating material, an effective thermal conductivity of the various layers of the semiconductor system may be increased, which may allow for increased heat dissipation and a lower operating temperature at a semiconductor apparatus.

In addition to applicability in memory systems as described herein, techniques for heat transfer structures for semiconductor apparatuses may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by including heat dissipation structures in various layers of a semiconductor system, which may reduce an operating temperature of the semiconductor system and allow for higher device density and power density, among other benefits.

Features of the disclosure are illustrated and described in the context of systems and architectures. Features of the disclosure are further illustrated and described in the context of semiconductor systems, semiconductor components, and flowcharts.

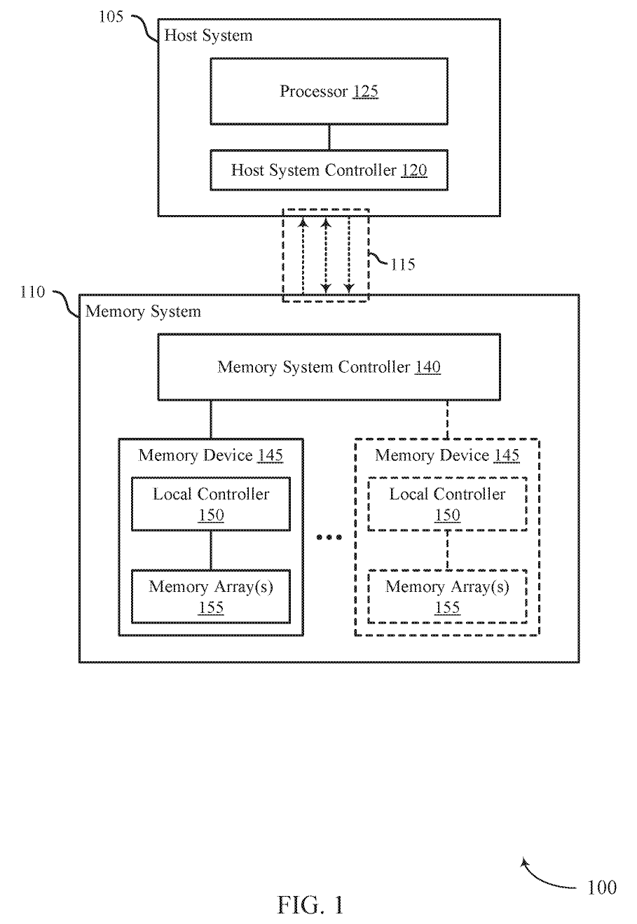

FIG. 1 shows an example of a system 100 that supports heat transfer structures for semiconductor apparatuses in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

In some examples, the system 100 or a host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of a system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks, or in one or more other dies. In some examples, multiple semiconductor dies of a memory system 110 or of a system 100 (e.g., an HBM system including aspects of a memory system 110, a stacked semiconductor system including aspects of a memory system 110 and a host system 105) may include one or more array dies stacked with one or more logic dies (e.g., that include aspects of the host system 105, that is coupled with another set of one or more dies that includes the host system 105) that includes interface blocks operable to access a set of memory arrays 155 distributed across the one or more second dies.

In some cases, a semiconductor apparatus (e.g., a system 100, a memory system 110, a host system 105, a processor 125, a memory system controller 140, memory device(s) 145) may be formed from one or more semiconductor components (e.g., one or more semiconductor dies). Such semiconductor components may be built from (e.g., on top of) a substrate, and circuitry may be formed at least in part from a front side of the substrate (e.g., a side that is doped to create transistors, for example). Additionally, each semiconductor component may include conductive lines (e.g., interconnection lines, access lines, conductive traces) in one or more interconnection layers over the substrate, which may interconnect the circuitry of the semiconductor component, circuitry of other semiconductor components, or both. In some cases, stacks of interconnection layers, and isolation layers therebetween, may decrease an effective thermal conductivity (e.g., increase an effective thermal resistance, reduce heat dissipation) of a semiconductor system, which may increase an operating temperature of the semiconductor system. For example, a semiconductor system may overheat as a result of the lower effective thermal conductivity, impede operations or cause damage to one or more components. In some examples, components of the semiconductor system may need to be separated (e.g., spread out) to reduce heat generation per volume, which may reduce spatial efficiency and operational capacity of the semiconductor system.

In accordance with aspects described herein, a semiconductor apparatus (e.g., a system 100, a memory system 110, a host system 105, a processor 125, a memory system controller 140, memory device(s) 145) may include thermal dissipation structures within or between semiconductor components to increase an effective thermal conductivity and reduce an operating temperature of the semiconductor apparatus. The thermal dissipation structures may include an electrically insulating material with a relatively high thermal conductivity (e.g., aluminum nitride (AlN)) or a conductive material (e.g., copper) to increase an effective thermal conductivity of the semiconductor apparatus. In some examples, an isolation layer (e.g., an interconnection layer that provides isolation or electrical separation between two or more conductive lines) may be formed between two interconnection layers and may include portions of an electrically insulating material with a relatively high thermal conductivity (e.g., higher than another dielectric material of the isolation layer). Additionally, or alternatively, an isolation layer may include one or more portions of a conductive material, and a dielectric layer may separate (e.g., electrically isolate) a portion of the conductive material in the isolation layer from a conductive line in one or more adjacent interconnection layers. Additionally, or alternatively, one or more portions (e.g., one or more pads, a layer) of an electrically insulating material with a relatively high thermal conductivity may be formed on an opposite side (e.g., a backside) of a substrate from the circuitry. In some cases, such portions of the electrically insulating material may separate a semiconductor substrate from one or more bonding pads. As a result of the relatively higher thermal conductivity of the conductive material and the electrically insulating material, an effective thermal conductivity of the various layers of the semiconductor system may be increased, which may allow for increased heat dissipation and a lower operating temperature at a semiconductor apparatus.

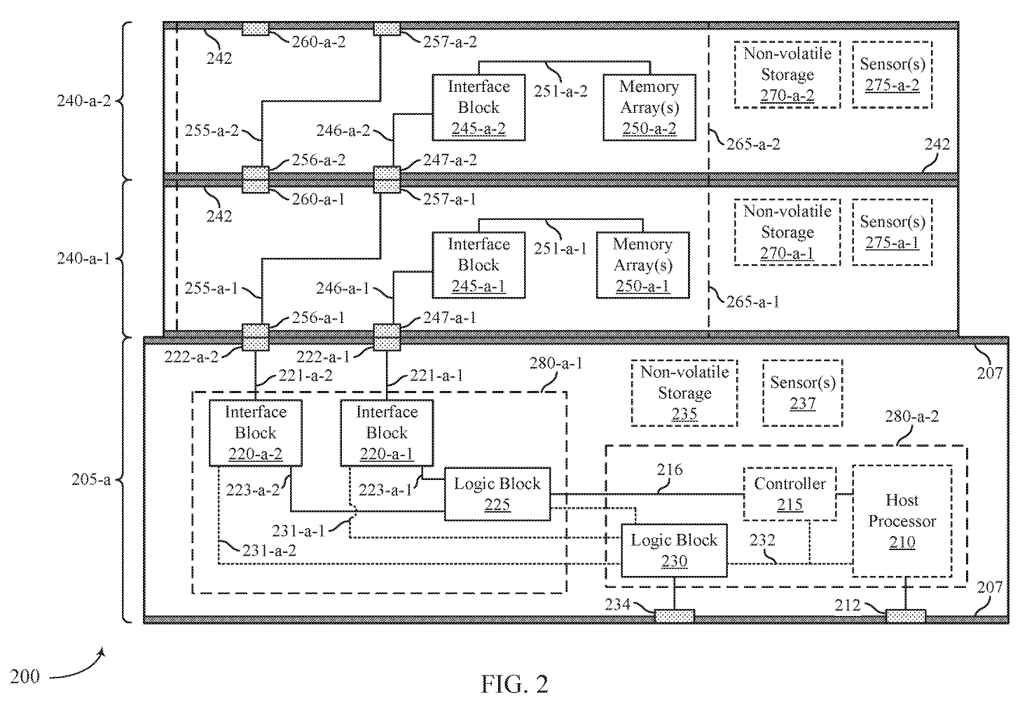

FIG. 2 shows an example of a system 200 (e.g., a semiconductor system, a system of coupled semiconductor dies, an HBM system, a 3D stacked memory system) that supports heat transfer structures for semiconductor apparatuses in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units, of a memory stack). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations, a die 205 may include a host processor 210. A host processor 210 may be an example of a host system 105, or a portion thereof (e.g., a processor 125, aspects of a host system controller 120, or both). A host processor 210 may include one or more processor cores that are configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a 3D stacked memory implementation, in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205-a with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube,” a memory stack, or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

Although described with reference to a 2:1 memory system configuration where two dies 240 are coupled with one die 205, the techniques described herein may be implemented in other configurations, such as a 4:1 configuration, a 4:2 configuration, a 2:2 configuration, a 8:1 configuration, a 12:1 configuration, a 16:1 configuration and so on, where an n:N configuration refers to a configuration with n dies 240 and N dies 205. In some examples (e.g., in 3D stacked memory systems there may be multiple (e.g., 4, 6, 8) n:N configuration stacks (e.g., 8:1 configuration, 12:1 configuration, 16:1 configuration) on a processor (e.g., a CPU, a GPU, as one or more dies 205 or coupled with one or more dies 205).

In some cases, semiconductor components such as one or more of the dies 205 and 240 may include a substrate and circuitry formed at least in part from a front side of the substrate. Additionally, such dies may include conductive lines (e.g., access lines, conductive traces) in one or more interconnection layers (e.g., FEOL layers, BEOL layers) over the substrate, which may interconnect the circuitry of the semiconductor component, circuitry of other semiconductor components, or both. Stacks of interconnection layers, and isolation layers therebetween, may decrease an effective thermal conductivity (e.g., increase an effective thermal resistance, reduce heat dissipation, along a thickness direction) of a system 200, or dies thereof, which may increase an operating temperature of the system 200. For example, a system 200 may overheat as a result of the lower effective thermal conductivity, which may impede operations or cause damage to one or more components. In some examples, components of a system 200 may need to be separated (e.g., spread out) to reduce heat generation per volume, which may reduce spatial efficiency and operational capacity of the system 200.

In accordance with aspects described herein, the system 200 may include thermal dissipation structures within or between the dies 205 and 240 to increase an effective thermal conductivity and reduce an operating temperature of the system 200. The thermal dissipation structures may include an electrically insulating material with a relatively high thermal conductivity (e.g., aluminum nitride (AlN)) or a conductive material (e.g., copper) to increase an effective thermal conductivity of the system 200. In some examples, an isolation layer (e.g., an interconnection layer that provides isolation or electrical separation between two or more conductive lines) may be formed between two interconnection layers and may include portions of an electrically insulating material with a relatively high thermal conductivity (e.g., higher than another dielectric material of the isolation layer). Additionally, or alternatively, an isolation layer may include one or more portions of a conductive material, and a dielectric layer may separate (e.g., electrically isolate) a portion of the conductive material in the isolation layer from a conductive line in one or more adjacent interconnection layers. Additionally, or alternatively, one or more portions (e.g., one or more pads, a layer) of an electrically insulating material with a relatively high thermal conductivity may be formed on an opposite side (e.g., a backside) of a substrate from the circuitry. In some cases, such portions of the electrically insulating material may separate a semiconductor substrate from one or more bonding pads. As a result of the relatively higher thermal conductivity of the conductive material and the electrically insulating material, an effective thermal conductivity of the various layers of the system 200 may be increased, which may allow for increased heat dissipation and a lower operating temperature at the system 200.

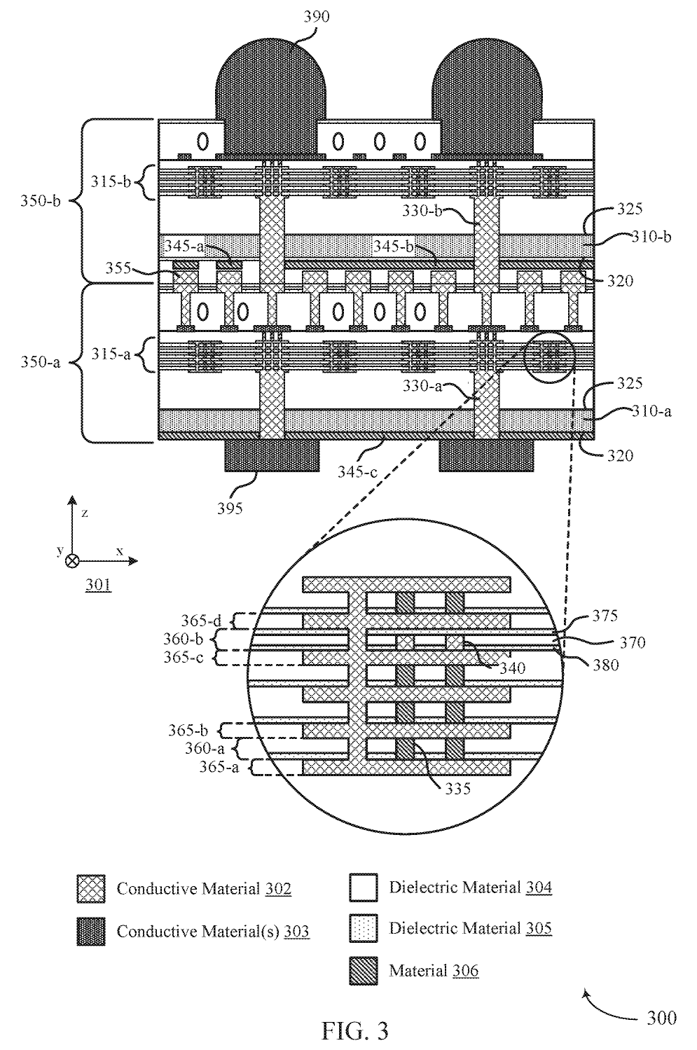

FIG. 3 shows a cross section of a semiconductor system 300 that supports (e.g., includes) heat transfer structures for semiconductor apparatuses in accordance with examples as disclosed herein. In some cases, aspects of the semiconductor system 300 may implement or be implemented by aspects of FIGS. 1 and 2. For example, the semiconductor system 300 may include semiconductor components 350 (e.g., a semiconductor component 350-a, a semiconductor component 350-b, semiconductor dies, semiconductor wafers, reconstructed semiconductor dies or wafers, examples of the dies 205 and/or 240), which may include substrates 310 (e.g., a substrate 310-a, a substrate 310-b, semiconductor substrates), conductive portions 355 (e.g., conductive pads, contact pads, examples of contacts as described with reference to FIG. 2), and vias 330 (e.g., a via 330-a, a via 330-b, examples of vias or TSVs as described with reference to FIG. 2). Additionally, the semiconductor system 300 may include interconnection layers and/or isolation layers in the portions 315 (e.g., a portion 315-a, a portion 315-b, FEOL portions, BEOL portions). Features of a semiconductor system 300 may be described with reference to an x-direction, a y-direction, and a z-direction of a coordinate system 301. In some aspects, the semiconductor system 300 may include one or more heat dissipation structures in the portions 315 of the substrates 310 or on a backside 320 of the substrates 310 (e.g., on a same side of the substrates 310 as the backside 320). Such heat dissipation structures may include portions 335 of a material 306, conductor portions 340 of a conductive material 302 (e.g., copper), or portions 345 of the material 306 on the backside 320 of the substrates 310, or a combination thereof.

The material 306 may be various examples of materials that have a relatively high thermal conductivity (e.g., greater than a thermal conductivity of the dielectric material 304), but are configured in a semiconductor apparatus for electrical isolation (e.g., as an electrically insulating material). For example, the material 306 may be a dielectric material, or may be a material that has semiconducting properties associated with a relatively high bandgap (e.g., higher than a bandgap implemented for semiconductor operations of the semiconductor system, a material that is not used for conducting or semiconducting properties). In other words, the material 306 may have dielectric properties throughout the operating conditions of a semiconductor system. Further, portions 335 may be separate (e.g., separated by portions of the dielectric materials 304 or 305) from conductors, such as vias, between interconnection layers 365. In some implementations, the material 306 may be AlN, or another material configured for electrical isolation and with a higher thermal conductivity than the dielectric material 304.

In some cases, a semiconductor system 300 (e.g., an HBM system, a 3D stacked memory system, another memory system or processing system) may have a relatively low thermal conductivity, which may lead to relatively high operating temperatures and overheating. For example, circuitry of layered semiconductor components 350 may generate heat, and interconnection layers in the portions 315 may include relatively large portions of a dielectric material 304 (e.g., an oxide of silicon, silicon oxide (SiOₓ), another dielectric material) having a relatively low thermal conductivity. In some cases, one or more of the dielectric materials 304 and dielectric material 305 may be examples of the dielectric material 207 described herein with reference to FIG. 2. Thus, heat that is generated, for example, by circuitry in a semiconductor component 350 may not dissipate easily through the portion 315-a and relatively high thermal gradients may be associated with relatively high operating temperatures of the semiconductor component 350.

In some systems, in an effort to increase effective thermal conductivity and reduce operating temperatures, a density of conductive lines, circuitry components, or both may be reduced (e.g., a space between the conductive lines may be increased). Additionally, or alternatively, solder-based thermal structures 390 (e.g., micro-bump (μ-bump) solder portions) may be used to reduce an operating temperature of the semiconductor system 300. However, decreased density of components and conductive lines may increase a size of the system, and solder-based thermal structures 390 may not be sufficient for supporting thermal conductivity within or through the system. Thus, as described herein, one or more thermal dissipation structures may be formed in (e.g., included in) a semiconductor system 300 to increase the thermal conductivity and reduce the operating temperature of the semiconductor system 300. Such thermal dissipation structures may increase the thermal conductivity and reduce the operating temperature of the semiconductor system 300, which may allow for a decreased size of the semiconductor system 300 (e.g., an increased density of components therein) and an increased speed or processing capacity of the semiconductor system 300.

In some examples, a semiconductor system 300 may include one or more portions 335 of the material 306 in one or more isolation layers 360. For example, portions 315 may include an isolation layer 360-a which may be between an interconnection layer 365-a and an interconnection layer 365-b (e.g., interconnection layers having conductive lines along the x-direction, along the y-direction or both). In some cases, an isolation layer 360-a may include one or more portions 335 of the material 306 (e.g., “dielectric vias”) extending through the dielectric material 304, where the material 306 may have a higher thermal conductivity than the dielectric material 304. For example, the material 306 may be AlN or another dielectric material, and the dielectric material 304 may be SiO or another dielectric material with a thermal conductivity lower than that of the material 306. In some cases, the portions 335 of the material 306 may be in contact with conductive lines of one or more of the interconnection layers 365-a and 365-b, and the portions 335 of the material 306 may increase a thermal conductivity between the interconnection layers 365. For example, the higher thermal conductivity of the material 306 may increase an effective thermal conductivity of the isolation layer 360-a (e.g., along the z-direction), which may allow more heat to dissipate through the portion 315 and reduce an operation temperature of the semiconductor system 300.

Additionally, or alternatively, a semiconductor system 300 may include one or more conductor portions 340 of a conductive material 302 (e.g., copper, another conductive material or metal) in one or more isolation layers 360. For example, an isolation layer 360-b may be between an interconnection layers 365-c and an interconnection layer 365-d of the portion 315. In some cases, the isolation layer 360-b may include a layer 375 of a dielectric material 305 and a layer 370 of a dielectric material 304, where the dielectric material 305 may be different from the dielectric material 304 (e.g., different materials, different concentrations). In some cases, the layer 375 of the dielectric material 305 may be between the layer 370 of the dielectric material 304 and an adjacent interconnection layer (e.g., such as the interconnection layer 365-d). The isolation layer 360-b may include one or more conductor portions 340 extending from a surface of the interconnection layer 365-c (e.g., or from a surface of a layer 380 of the dielectric material 305), through the layer 370 of the dielectric material 304, and to a surface of the layer 375 of the dielectric material 305. For example, conductor portions may extend through the layer 370 of the dielectric material 304 and may be separated from one or both of the adjacent interconnection layers 365 (e.g., from one or more conductive lines in the adjacent interconnection layers 365) by one or more layers of the dielectric material 305 (e.g., such as the layers 375 or 380, or both). Conductor portions 340 may increase an effective thermal conductivity of the isolation layer 360-b without causing unintended shorts between the interconnection layers 365 based on the layer 375, layer 380, or both of the dielectric material 305.

Additionally, or alternatively, a semiconductor system 300 may include one or more portions 345 of the material 306 on the backside 320 of the substrate 310. For example, a substrate 310 may support circuitry formed at least in part from a doped portion of the substrate 310, and the side of the substrate 310 that includes the doped portion may be the front side 325 of the substrate 310, and a side opposite the doped portion may be the backside 320 of the substrate 310. One or more portions 345 of the material 306 may be formed on the backside 320 of the substrate 310 (e.g., over the backside 320 of the substrate 310, directly in contact with or not directly in contact with the backside 320 of the substrate 310), where the material 306 may have a higher thermal conductivity than the dielectric material 304. In some examples, portions 345 of the material 306 may include separate portions 345-a of the material 306 (e.g., pads) that each separate a respective conductive portion 355 from the substrate 310 along the z-direction. Additionally, or alternatively, portions 345 may include a single portion 345-b of the material 306 (e.g., a layer) that covers some or all of the backside 320 of the substrate 310 and separate the substrate 310 from conductive portions 355. Additionally, or alternatively, portions 345 may include a portion 345-c (e.g., a single portion) formed directly on the backside 320 of the substrate 310, and one or more vias 330 may pass through the portion 345-c (e.g., or the single portion 345-b) of the material 306. In some cases, the portions 345 of the material 306 on the backsides 320 of the substrates 310 may increase a thermal conductivity between semiconductor components 350 (e.g., or a semiconductor component 350-a and a conductive pad 395 of one or more conductive material(s) 303 (e.g., nickel (Ni))) to reduce an operating temperature of the semiconductor system 300.

The heat dissipation structures described herein may lower an operating temperature of the semiconductor system 300 by increasing a rate at which heat dissipates through or from the semiconductor system 300. Such lower operating temperatures may increase computing abilities and increase material integrity of the semiconductor system 300. Additionally, the semiconductor system 300 may be manufactured with a smaller size, with components being closer together (e.g., more “densely” manufactured) based on the improved heat dissipation properties of the semiconductor system 300.

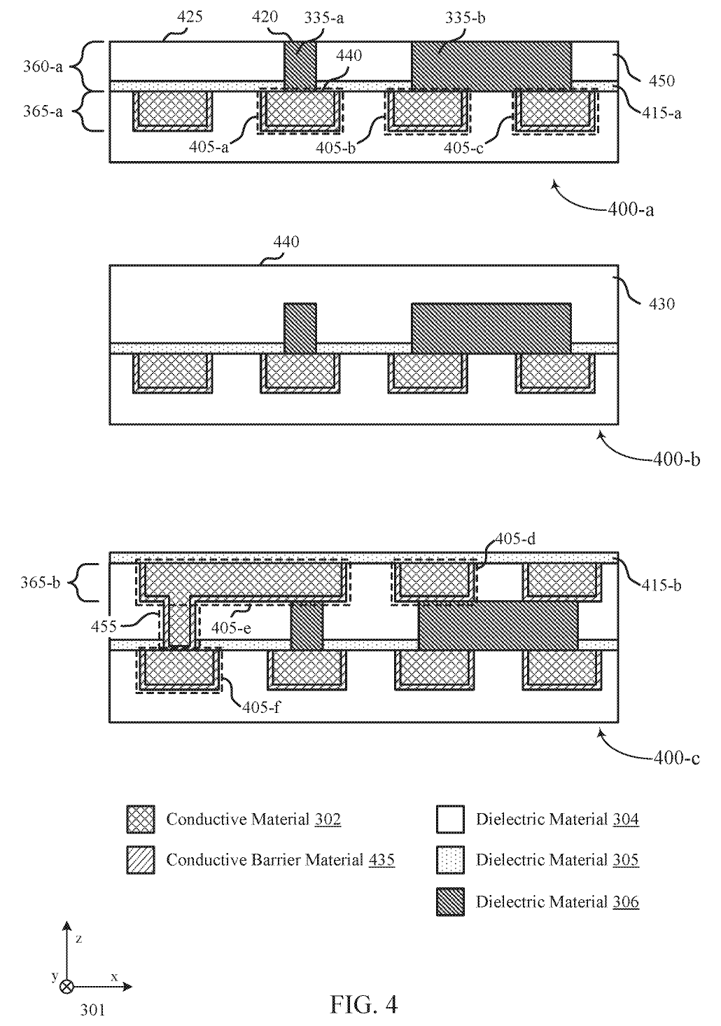

FIG. 4 shows cross sections of a semiconductor component 400 (e.g., as semiconductor components 400-a, 400-b, and 400-c, a semiconductor apparatus) that support heat transfer structures in accordance with examples as disclosed herein. For example, each illustration may show a semiconductor component 400 in a different stage of manufacturing (e.g., illustrating one or more manufacturing operations). In some cases, aspects of a semiconductor component 400 may implement or be implemented by aspects of FIG. 1–3. For example, a semiconductor component 400 may include portions 335 of the material 306, an isolation layer 360-a, and interconnection layers 365 (e.g., interconnection layers 365-a and 365-b) of a portion 315. The semiconductor component 400 may also include the conductive material 302, the dielectric material 304, the dielectric material 305, and the material 306. Features of the semiconductor component 400 may be described with reference to the x-direction, the y-direction, and the z-direction of the coordinate system 301. As illustrated, the semiconductor component 400-c may include formed portions 335 of the material 306.

310 (e.g., along the x-direction, along the y-direction, or both). For example, after doping a portion of the substrate 310 (e.g., a front side 325), circuitry may be formed at least in part from the doped portion of the substrate 310, and conductive lines 405 of the interconnection layer 365-a may be electrically coupled with the circuitry. For example, the interconnection layer 365-a may be along a same side of the substrate as the doped portion of the substrate (e.g., may be on the front side of the substrate). The conductive lines 405 may be in direct contact with the substrate 310 (e.g., via terminal contacts coupled with circuitry of the substrate) or may be separated from the substrate 310 by one or more other materials, (e.g., a dielectric material, gate dielectric portions). In some examples, conductive lines 405 may be formed by forming a conductive barrier material 435 (e.g., titanium nitride (TiN)) along cavity surfaces, and forming a conductive material 302 (e.g., copper) in the conductive barrier material 435. The conductive barrier material 435 may suppress material diffusion between the conductive material 302 and the dielectric material 304

The isolation layer 360-a (e.g., in an xy-plane) may be formed over (e.g., along the z-direction) the interconnection layer 365-a, and may include one or more portions 335 of the material 306. Portions 335 may extend through (e.g., along the z-direction) the dielectric material 304 in the isolation layer 360-a, and the material 306 may have a higher thermal conductivity than the dielectric material 304. For example, the material 306 may be AlN, and the dielectric material 304 may be a silicon oxide.

Forming the isolation layer 360-a may include one or more formation operations. For example, forming the isolation layer 360-a may include forming a layer 415-a of the dielectric material 305 over the interconnection layer 365-a (e.g., in contact with the conductive lines 405), and forming a layer 450 of the dielectric material 304 over the layer 415-a and over the interconnection layer 365-a. In some cases, the dielectric material 305 may include a barrier dielectric material with a low thermal conductivity (e.g., barrier low K (BLOK)), such as silicon carbonitride (SiCN) or other dielectric materials, and the dielectric material 304 may be an oxide of silicon (e.g., SiOₓ). Forming the isolation layer 360-a may also include forming one or more cavities into the layer 450 of the dielectric material 304 and, in some examples, into the layer 415-a of the dielectric material 305 and forming the one or more portions 335 of the material 306 in the one or more cavities. In some cases, one or more portions 335 of the material 306 may extend from (e.g., be in contact with) a surface 440 of one or more of the conductive lines 405. For example, the layer 415-a of the dielectric material 305 may be perforated prior to forming the portions 335 to allow for increased heat transfer between the conductive lines 405 and the portions 335. Alternatively, the layer 415-a may not be perforated (e.g., for ease of manufacturing), and portions 335 may extend from a surface of the dielectric material 305 (not shown).

In some cases, the one or more portions 335 of the material 306 may include one or more vias (e.g., thermal vias), one or more bars (e.g., thermal bars), or both. For example, the portion 335-a of the material 306 may be a via, as the portion 335-a may be formed with a same pitch (e.g., regular distance between, along the x-direction) as the conductive lines 405. For example, the portion 335-a may be formed above the conductive line 405-a, and no part of the portion 335-a may be above (e.g., along the z-direction) another conductive line 405 of the interconnection layer 365-a. The portion 335-a may have a circular, square, or polygonal shape in an xy-plane over the conductive line 405-a.

In some other examples, bars, such as the portion 335-b of the material 306, when viewed along the z-direction (e.g., along a direction from the substrate), may overlap with a respective set of multiple conductive lines 405 of the interconnection layer 365-a (e.g., or of another interconnection layer 365, or both). For example, the portion 335-b may be a bar, and may be formed along at least one direction (e.g., along the x-direction) to extend for a multiple of the pitch of the conductive lines 405, such that the portion 335-b may be over (e.g., in contact with, overlapping with) the conductive lines 405-b and 405-c. In some cases, a larger mass of the bars when compared to vias of the material 306 may increase a proportion of the isolation layer 360-a that has the higher thermal conductivity, which may reduce operating temperatures of the semiconductor component 400. Additionally, as the material 306 may act as an isolating (e.g., dielectric) material under the operating conditions of the semiconductor component 400, the bars may not electrically couple the conductive lines 405-b and 405-c, but may increase a thermal conductivity between the conductive lines 405-b and 405-c, allowing heat to dissipate through the semiconductor component 400.

In the example of semiconductor component 400-b, a layer 430 of the dielectric material 304 may be formed over the isolation layer 360-a. For example, after forming the material 306 (e.g., into cavities formed in the semiconductor component 400-a), a chemical-mechanical polishing (CMP) operation may be performed on a surface 420 of the portions 335 of the material 306, a surface 425 of the dielectric material 304, or both. The layer 430 of the dielectric material 304 may be deposited above (e.g., in contact with) the surfaces 420 and 425, and a surface 440 of the layer 430 may receive a CMP operation to prepare for future forming operations. In some cases, the layer 430 of the dielectric material 304 may be part of the interconnection layer 365-b.

In the example of semiconductor component 400-c, the interconnection layer 365-b may be formed over the isolation layer 360-a. In some cases, the interconnection layer 365-b may include one or more conductive lines 405 (e.g., second conductive lines) that extend (e.g., along the x-direction, along the y-direction, or both) over the isolation layer 360-a and the substrate. In some cases, the conductive lines 405 in the interconnection layer 365-b may be electrically coupled with the circuitry of the substrate. Additionally, or alternatively, at least one of the one or more portions 335 of the material 306 may extend from (e.g., be in contact with) a surface of one or more of the conductive lines 405 in the interconnection layer 365-a, a surface of one or more of the conductive lines 405 in the interconnection layer 365-b, or both. In some cases, the conductive lines 405 in the interconnection layers 365 may include a conductive barrier material 435 over the conductive material 302. For example, one or more of the portions 335 of the material 306 may extend from (e.g., be in contact with) a surface of the conductive barrier material 435.

The conductive lines 405 may be formed with a single damascene operation, a dual damascene operation, or both. For example, a conductive line 405 formed with a single damascene operation (e.g., conductive lines 405-a, 405-b, 405-c, and 405-d) may be formed within an interconnection layer 365 (e.g., with a single depth of conductor formation along the z-direction), and may contact the surface 420 of one or more portions 335 of the material 306 or a surface of the isolation layer 360-a (e.g., if no portion 335 of the material 306 is formed beneath the conductive line 405). For example, the conductive line 405-d may be formed with a single damascene operation, and may extend from a top surface of the portion 335-b to a layer 415-b of the dielectric material 305 over the interconnection layer 365-b.

Conductive lines 405 formed with a dual damascene operation (e.g., conductive line 405-d) may be formed concurrently with conductive via portions (e.g., a conductive via portion 455) that extend to another interconnection layer 365 (e.g., through an isolation layer 360, with two depths of conductor formation along the z-direction). For example, the conductive line 405-e may be formed with a dual damascene operation, where the conductive via portion 455 may extend (e.g., along the z-direction) from the conductive line 405-f of the interconnection layer 365-a to the conductive line 405-e, and the conductive line 405-e may extend (e.g., along the z-direction) from a top of the conductive via portion 455 to the layer 415-b of the dielectric material 305 over the interconnection layer 365-b. The portions of the dual damascene conductive lines in different layers (e.g., in the interconnection layer 365-b and the isolation layer 360-a) may be formed continuously (e.g., in the same process(es)). That is, dual damascene may include concurrent formation of relatively wider conductive lines 505 at a relatively shallower depth (e.g., in the interconnection layer 356-b) connected with relatively narrower conductive via portions 455 or conductive lines 405 at a relatively deeper depth (e.g., through the isolation layer 360-a).

Accordingly, by including portions 335 of the material 306 between conductive lines 405 the semiconductor component 400 may be associated with a higher relative thermal conductivity, which may allow for greater heat dissipation from the semiconductor component 400 and lower operating temperatures of the semiconductor component 400.

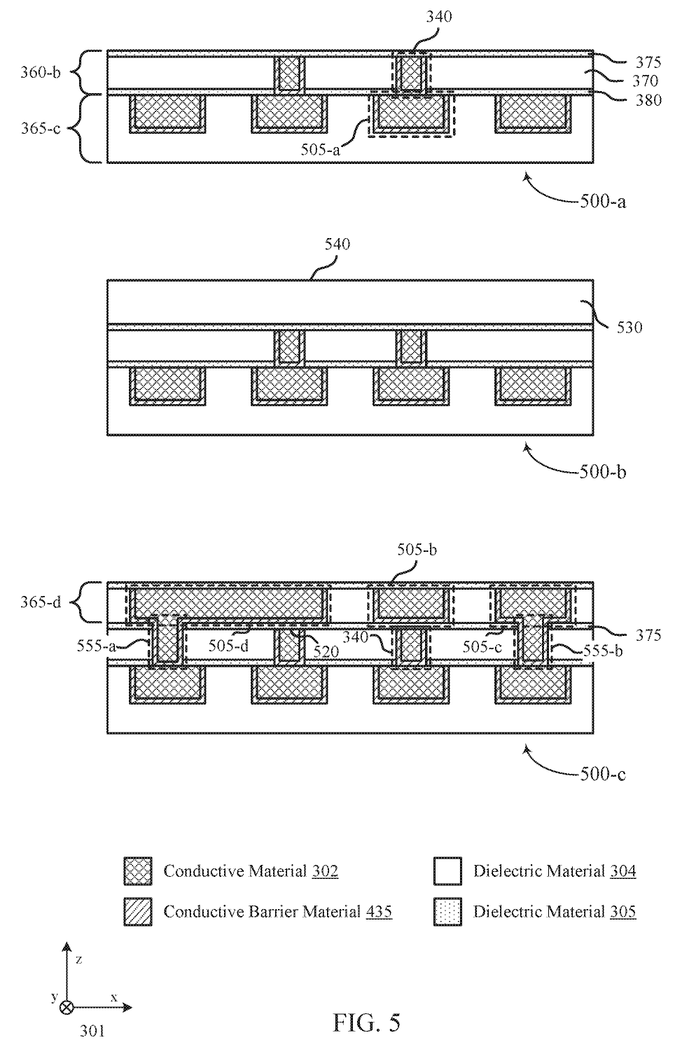

FIG. 5 shows cross sections of a semiconductor component 500 (e.g., as semiconductor components 500-a, 500-b, and 500-c) that support heat transfer structures in accordance with examples as disclosed herein. For example, each illustration may show a semiconductor component 500 in a different stage of manufacturing (e.g., illustrating one or more manufacturing operations). In some cases, aspects of the semiconductor component 500 may implement or be implemented by aspects of FIG. 1–4. The semiconductor component 500 may include one or more conductor portions 340 (e.g., of the conductive material 302, of the conductive barrier material 435, or both), an isolation layer 360-b, interconnection layers 365 (e.g., the interconnection layers 365-c and 365-d), layers 375 and 380 of the dielectric material 305, and a layer 370 of the dielectric material 304. Additionally, the semiconductor components 500 may also include one or more conductive lines 505 and conductive via portions 555, which may be examples of the conductive lines 405 and the conductive via portion 455 described with reference to FIG. 4 (e.g., conductive lines 505-c and 505-d which may be formed concurrently with conductive via portions 555-a and 555-b, respectively, in accordance with dual damascene operations). Features of the semiconductor component 500 may be described with reference to the x-direction, the y-direction, and the z-direction of the coordinate system 301. As illustrated, the semiconductor component 500 may include formed conductor portions 340.

In the example of semiconductor component 500-a, interconnection layer 365-c may be formed over a substrate 310 (not shown). In some cases, the interconnection layer 365-c (e.g., along an xy-pane) may include one or more conductive lines 505 that extend (e.g., along the x-direction, along the y-direction, or both) over the substrate (e.g., conductive line 505-a, first conductive lines). In some cases, the conductive lines 505 of the interconnection layer 365-c may be formed similarly to the conductive lines 405, and the conductive lines may be in direct contact with the substrate 310 or may be separated from the substrate 310 by one or more materials (e.g., as described herein with reference to FIG. 4). Additionally, the conductive lines 505 of the interconnection layer 365-c may electrically couple with circuitry of the substrate and may be on the front side of the substrate.

An isolation layer 360-b (e.g., along an xy-plane) may be formed over the interconnection layer 365-c. For example, the layer 380 of the dielectric material 305 may be formed over the interconnection layer 365-c (e.g., in contact with a top surface of the one or more conductive lines of the interconnection layer 365-c) and the layer 370 of the dielectric material 304 may be formed over the layer 380 and the interconnection layer 365-c. One or more cavities may be formed through the layer 370, the layer 380, or both, which may expose conductive lines 505 of the interconnection layer 365-c or a surface of the layer 380. A respective conductor portion 340 may then be formed in each of the one or more cavities.

In some cases, similar to the conductive lines 405 and 505, each respective conductor portion 340 may include multiple conductive materials. For example, forming each conductor portion 340 may include forming a conductive barrier material 435 along a sidewall of a respective cavity, where the conductive barrier material 435 may be in contact with a respective conductive line 505. For example, the conductive barrier material 435 of the conductor portion 340 may be in contact with the conductive lines 505-a of the interconnection layer 365-c. The conductive material 302 may be formed within (e.g., over) the conductive barrier material 435 within each cavity to form the conductor portions 340.

In some cases, a layer 375 (e.g., along an xy-plane) of the dielectric material 305 may be formed over the layer 370 of the dielectric material 304 and over the conductor portions 340. For example, a CMP process may be performed on a top surface of the layer 370 and the conductor portions 340 (e.g., a surface that is furthest along the z-direction), and the layer 375 may be deposited on top of the top surface (e.g., of layer 370) after the CMP process.

In the example of semiconductor component 500-b, a layer 530 (e.g., along an xy-plane) of the dielectric material 304 may be formed above (e.g., along the z-direction) the layer 375 of the dielectric material 305. For example, the layer 530 may be part of the interconnection layer 365-d. In some cases, a top surface 540 of the layer 530 may receive a CMP process in preparation for further operations to form an interconnection layer 365-d.

In the example of semiconductor component 500-c, the interconnection layer 365-d (e.g., along an xy-plane) may be formed over the layer 375 of the dielectric material 305. In some cases, the interconnection layer 365-d may include one or more conductive lines 505 (e.g., second conductive lines) that extend over the substrate and are separated (e.g., in the z-direction) from respective conductor portions 340 by the layer 375 (e.g., a portion of the layer 375) of the dielectric material 305. For example, one or more conductor portions 340 may be in contact with a surface 520 of the layer 375 of the dielectric material 305 instead of the conductive lines 505 of the interconnection layer 365-d. Accordingly, the conductor portions 340 may increase a thermal conductivity of the isolation layer 360-b without unintentionally shorting conductive lines 505 from different interconnection layer 365.

In some cases, one or more of the conductive lines 505 in the interconnection layer 365-d may be formed with the dual damascene process, as described with reference to FIG. 4. For example, forming the conductive lines 505-c and 505-d may include forming conductive via portions 555-a and 555-b, respectively, that may electrically couple (e.g., through the layers 370, 375, and 380) the conductive line 505-c or 505-d with a respective one of the conductive lines 505 of the interconnection layer 365-c. Additionally, or alternatively, the conductive via portions 555 may extend from a corresponding conductive lines 505 through one or more of the layers 370, 375, and 380 without contacting a conductive line 505 in the interconnection layer 365-c. The conductive lines 505-c and 505-d may be formed continuously with the conductive via portions 555-a and 555-b, respectively, according to the dual damascene process.

Additionally, or alternatively, the conductor portions 340 may include one or more vias (e.g., electrically disconnected vias, thermal vias), one or more bars (e.g., thermal bars), or both (e.g., as described with reference to FIG. 4). For example, the conductor portion 340 may be a via that is electrically coupled with (e.g., in contact with) a conductive line of the interconnection layer 365-c and electrically isolated from a conductive line 505-b because of the layer 375 of the dielectric material 305. Additionally, or alternatively, at least one of the conductor portions 340 may be a bar and, when viewed in an xy-plane along the z-direction (e.g., in a direction from the substrate), may overlap with a respective set of multiple conductive lines 505 of the plurality of conductive lines of the interconnection layer 365-c, the interconnection layer 365-d, or both (e.g., separated from the multiple conductive lines 505 by the layer 375 of the dielectric material 305). For example, the conductor portion 340 may extend along the y-direction for a length that is a multiple of the pitch between the conductive lines 505 along the y-direction, forming a bar. Additionally, or alternatively, a conductor portion 340 that is a bar may be formed to extend along the x-direction for a length that is a multiple of the pitch between the conductive lines 505 along the x-direction.

Accordingly, by conductor portions 340 between conductive lines 505, the semiconductor component 500 may be associated with a higher relative thermal conductivity, which may allow for greater heat dissipation from the semiconductor component 500 and lower operating temperatures of the semiconductor component 500.

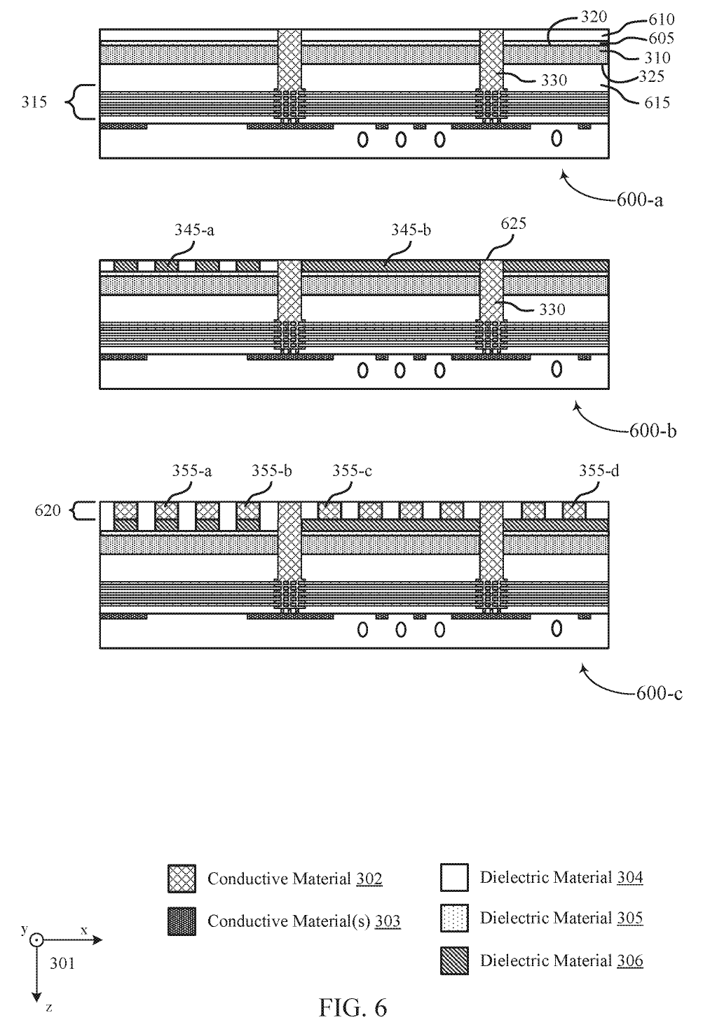

FIG. 6 shows cross sections of a semiconductor component 600 (e.g., as semiconductor components 600-a, 600-b, and 600-c) that support heat transfer structures in accordance with examples as disclosed herein. For example, each illustration may show a semiconductor component 600 in a different stage of manufacturing (e.g., illustrating one or more manufacturing operations). In some cases, aspects of the semiconductor component 600 may implement or be implemented by aspects of FIG. 1–5. For example, the semiconductor component 600 may include the substrate 310 with the front side 325 and the backside 320, the portion 315 of the semiconductor component 600, one or more vias 330, the one or more portions 345 of the material 306, and the one or more conductive portion 355. Features of the semiconductor component 600 may be described with reference to the x-direction, the y-direction, and the z-direction of the coordinate system 301. Compared to FIG. 3–5, the coordinate system 301 as shown in FIG. 6 may be rotated 180 degrees around the x-direction, such that the cross sections of the semiconductor component 600 may be upside-down compared to the cross section of the semiconductor system 300 and semiconductor components 400 and 500. As illustrated, the semiconductor component 600 may include formed portions 345 of the material 306 on the backside 320 of the substrate 310.

In the example of semiconductor component 600-a, circuitry may be formed at least in part from a doped portion of the substrate 310. For example, the front side 325 of the substrate 310 may be doped, and the circuitry may be formed at least partially therefrom. A layer 615 (e.g., along an xy-plane) of the dielectric material 304 may be formed over the circuitry on the front side 325 of the substrate 310. Additionally, one or more heat dissipation structures may be formed within the portion 315 (e.g., such as one or more of those described herein with reference to FIGS. 3, 4, and 5).

On the backside 320 of the substrate 310, one or more layers may be formed. For example, a layer 605 of the dielectric material 305 may be formed over the backside 320. Additionally, or alternatively, a layer 610 of the dielectric material 304 may be formed over the backside 320 (e.g., and over the layer 605 if formed). In some cases, no layer of dielectric materials 304 or 305 may be formed on the backside 320 of the substrate 310.

In the example of semiconductor component 600-b, one or more portions 345 of the material 306 may be formed over (e.g., in an xy-plane, along the negative z-direction from) the backside 320 of the substrate 310. For example, the material 306 may have a higher thermal conductivity than the dielectric materials 304 and 305 (e.g., AlN). In a case where the layer 610 of the dielectric material 304 is formed on the semiconductor component 600-a, forming the one or more portions 345 of the material 306 may include forming voids in the layer 610 (e.g., exposing the backside 320 of the substrate 310 or a surface of the layer 605, if formed) and filling the voids with the material 306. For example, the portion 345-a may be formed within voids of the layer 610. However, if no layer 610 was formed in the semiconductor component 600-a, a portion 345-b (e.g., a film, a layer, a pad) may be formed on the backside 320 of the substrate 310 or on the layer 605 (e.g., if formed). For example, the portion 345-a may be substantially circular, square, or regularly polygonal in an xy-plane, and the portion 345-b may expand to cover a relatively larger portion (e.g., an entire surface, less than an entire surface) of the backside 320 of the substrate 310 in an xy-plane.

In some cases, one or more vias 330 (e.g., conductive vias, through-silicon vias (TSVs), of the conductive material 302) may be formed through the substrate 310 (e.g., along the y-direction) and may be electrically coupled with the circuitry of the front side 325 of the substrate 310. In some cases, the one or more vias 330 may also be formed through one of the one or more portions 345 of the material 306. For example, after forming the portion 345-b, a void may be formed through the portion 345-b exposing the one or more vias 330, and the void may be filled with the conductive material 302, which may effectively extend a surface 625 of the via 330 through the portion 345-b.

In some cases, the semiconductor component 600-b may be attached to one or more conductive pads (e.g., such as the conductive pads 395 described with reference to FIG. 3). For example, the one or more conductive pads may each be in contact with a respective one of the one or more vias 330 and may be in contact with a corresponding one of the one or more portions 345 of the material 306. Additionally, or alternatively, if the vias 330 extend through a single portion 345-b of the material 306, the conductive pads may be in contact with the same portion 345-b of the material 306. Such conductive pads may be made of nickel (Ni) or another conductive material and may be used for transmitting power or communications to the circuitry of the substrate 310 from one or more external sources or devices.

In the example of semiconductor component 600-c (e.g., if the semiconductor component 600-b is not attached to the one or more conductive pads 395), a layer 620 (e.g., along an xy-plane) may be formed over the one or more portions 345 of the material 306 on the backside 320 of the substrate 310. In some cases, the layer 620 may include one or more conductive portions 355 which may extend through one or more portions of the dielectric material 304 (e.g., along the y-direction). For example, after performing a CMP process to flatten a surface of the portions 345 of the material 306, the vias 330, and the dielectric material 304 of the semiconductor component 600-b, the dielectric material 304 may be formed over the surface. One or more voids may be formed in the dielectric material 304, where the one or more voids may expose a corresponding portion 345-a of the material 306 or a section of a portion 345-b of the material 306. The conductive material 302 may be formed in each void to form the one or more conductive portions 355.

In a case where the one or more portions 345 of the material 306 include individually separate portions 345 (e.g., AlN backside passivation pads), such as the portion 345-a, at least one of the one or more conductive portions 355 may be formed over (e.g., an in contact with) a respective one of the one or more portions 345 of the material 306. For example, the conductive portion 355-a may be in contact with a portion 345 of the material 306 that is different than a portion 345 of the material 306 in contact with a conductive portion 355-b. In a case where the one or more portions 345 of the material 306 include a relatively larger layer of the material 306 (e.g., such as the portion 345-b, an AlN backside passivation layer), one or more of the one or more conductive portions 355 may be in contact with a same portion 345 of the material 306. For example, a conductive portion 355-c and a conductive portion 355-d may be in contact with the same portion 345-b of the material 306. Conductive portions 355 may not be implemented for carrying electrical power or signaling but may be metal components that are coupled with (e.g., soldered with, fused with) corresponding conductive portions 355 of another semiconductor component or other heat transfer component to be bonded via conductive portions 355.

In some cases, the portions 345 of the material 306 may increase a thermal conductivity between the one or more conductive portions 355 and the substrate 310, which may allow for more heat dissipation and reducing operating temperatures at the semiconductor component 600-c. Additionally, separate portions 345 of the material 306 may reduce a capacitive coupling or signal interference associated with the portions 345 of the material 306 (e.g., compared to a larger layer of the material 306, such as the portion 345-b). Alternatively, the portion 345-b (e.g., a larger layer of the material 306) may increase a thermal conductivity of the semiconductor component 600-c compared to the separate portions 345, allowing for reduced operating temperatures compared to the separate portions 345. Accordingly, the semiconductor component 600-c may have an increased effective thermal conductivity and reduced operating temperature.

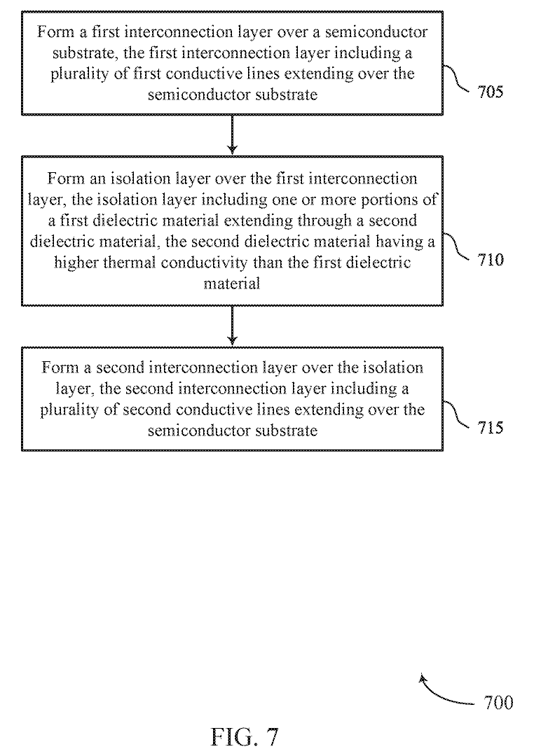

FIG. 7 shows a flowchart illustrating a method or methods 700 that supports heat transfer structures for semiconductor apparatuses in accordance with examples as disclosed herein. The operations of method 700 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 705, the method 700 may include forming a first interconnection layer (e.g., a first interconnection layer 365) over a semiconductor substrate (e.g., a substrate 310), the first interconnection layer including a plurality of first conductive lines (e.g., first conductive lines 405) extending over the semiconductor substrate.

At 710, the method 700 may include forming an isolation layer (e.g., an isolation layer 360) over the first interconnection layer, the isolation layer including one or more portions (e.g., portions 335) of a first dielectric material (e.g., a material 306) extending through a second dielectric material (e.g., a dielectric material 304), the second dielectric material having a higher thermal conductivity than the first dielectric material

At 715, the method 700 may include forming a second interconnection layer (e.g., a second interconnection layer 365) over the isolation layer, the second interconnection layer including a plurality of second conductive lines (e.g., second conductive lines 405) extending over the semiconductor substrate.

In some examples, an apparatus (e.g., a manufacturing system) as described herein may perform a method or methods, such as the method 700. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a first interconnection layer over a semiconductor substrate, the first interconnection layer including a plurality of first conductive lines extending over the semiconductor substrate; forming an isolation layer over the first interconnection layer, the isolation layer including one or more portions of a first dielectric material extending through a second dielectric material, the second dielectric material having a higher thermal conductivity than the first dielectric material; and forming a second interconnection layer over the isolation layer, the second interconnection layer including a plurality of second conductive lines extending over the semiconductor substrate.

Aspect 2: The method or apparatus of aspect 1, where at least one of the one or more portions of the first dielectric material extends from a surface of one or more of the plurality of first conductive lines, from a surface of one or more of the plurality of second conductive lines, or both.

Aspect 3: The method or apparatus of aspect 2, where the one or more of the plurality of first conductive lines, the one or more of the plurality of second conductive lines, or both include a conductive barrier material over a second conductive material and the at least one of the one or more portions of the first dielectric material extends from a surface of the conductive barrier material.

Aspect 4: The method or apparatus of any of aspects 1 through 3, where at least one of the one or more portions of the first dielectric material, when viewed along a direction from the semiconductor substrate, is overlapping with a respective set of multiple first conductive lines of the plurality of first conductive lines, with a respective set of multiple second conductive lines of the plurality of second conductive lines, or both.

Aspect 5: The method or apparatus of any of aspects 1 through 4, further including operations, features, circuitry, logic, means, or instructions, or any combination thereof for forming circuitry based at least in part on doping a portion of the semiconductor substrate, where the circuitry is electrically coupled with the plurality of first conductive lines and the plurality of second conductive lines, and where the first interconnection layer is along a same side of the semiconductor substrate as the doped portion of the semiconductor substrate.

Aspect 6: The method or apparatus of any of aspects 1 through 5, where forming the isolation layer including the one or more portions of the first dielectric material includes operations, features, circuitry, logic, means, or instructions, or any combination thereof for forming a layer of the second dielectric material over the first interconnection layer; forming one or more cavities in the layer of the second dielectric material; and forming the one or more portions of the first dielectric material in the one or more cavities.

Aspect 7: The method or apparatus of any of aspects 1 through 6, where the first dielectric material includes AlN and the second dielectric material includes SiO.

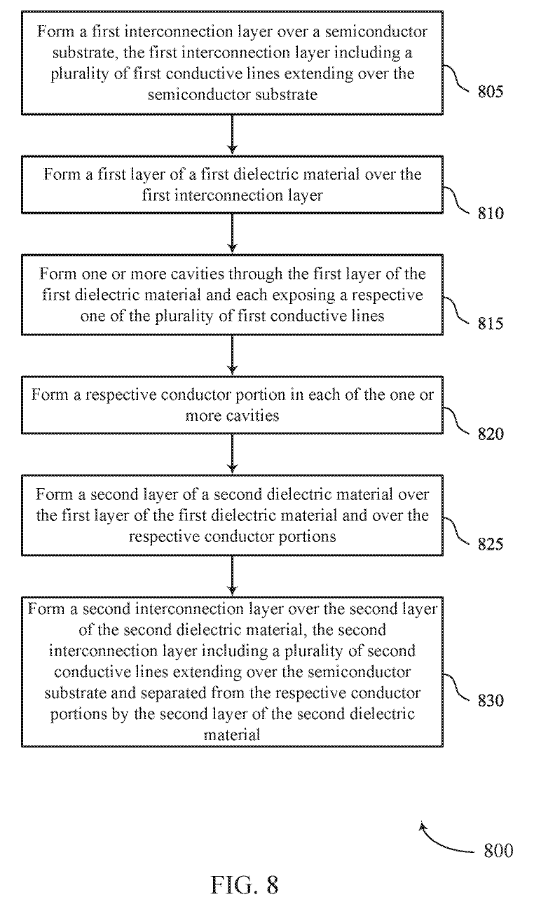

FIG. 8 shows a flowchart illustrating a method 800 that supports heat transfer structures for semiconductor apparatuses in accordance with examples as disclosed herein. The operations of method 800 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 805, the method may include forming a first interconnection layer (e.g., a first interconnection layer 365) over a semiconductor substrate (e.g., a substrate 310), the first interconnection layer including a plurality of first conductive lines (e.g., conductive lines 505) extending over the semiconductor substrate.

At 810, the method may include forming a first layer (e.g., a layer 380, a layer 370, or both) of a first dielectric material (e.g., a dielectric material 305, a dielectric material 304) over the first interconnection layer.

At 815, the method may include forming one or more cavities through the first layer of the first dielectric material and each exposing a respective one of the plurality of first conductive lines.

At 820, the method may include forming a respective conductor portion (e.g., a conductor portion 340) in each of the one or more cavities.

At 825, the method may include forming a second layer (e.g., a layer 375) of a second dielectric material (e.g., a dielectric material 305) over the first layer of the first dielectric material and over the respective conductor portions.

At 830, the method may include forming a second interconnection layer (e.g., a second interconnection layer 365) over the second layer of the second dielectric material, the second interconnection layer including a plurality of second conductive lines (e.g., second conductive lines 505) extending over the semiconductor substrate and separated from the respective conductor portions by the second layer of the second dielectric material.

In some examples, an apparatus (e.g., a manufacturing system) as described herein may perform a method or methods, such as the method 800. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 8: A method or apparatus including operations, features, circuitry, logic, means, or instructions, or any combination thereof for forming a first interconnection layer over a semiconductor substrate, the first interconnection layer including a plurality of first conductive lines extending over the semiconductor substrate; forming a first layer of a first dielectric material over the first interconnection layer; forming one or more cavities through the first layer of the first dielectric material and each exposing a respective one of the plurality of first conductive lines; forming a respective conductor portion in each of the one or more cavities; forming a second layer of a second dielectric material over the first layer of the first dielectric material and over the respective conductor portions; and forming a second interconnection layer over the second layer of the second dielectric material, the second interconnection layer including a plurality of second conductive lines extending over the semiconductor substrate and separated from the respective conductor portions by the second layer of the second dielectric material.

Aspect 9: The method or apparatus of aspect 8, further including operations, features, circuitry, logic, means, or instructions, or any combination thereof for forming a plurality of second conductor portions, each electrically coupling a respective one of the plurality of second conductive lines with a respective one of the plurality of first conductive lines through the second layer of the second dielectric material and through the first layer of the first dielectric material, and each formed continuously with the respective one of the plurality of second conductive lines.

Aspect 10: The method or apparatus of any of aspects 8 through 9, where forming a conductive barrier material along a sidewall of a respective cavity and in contact with the respective one of the plurality of first conductive lines and forming a second conductive material over the conductive barrier material.

Aspect 11: The method or apparatus of any of aspects 8 through 10, where at least one of the respective conductor portions, when viewed along a direction from the semiconductor substrate, is overlapping with a respective set of multiple second conductive lines of the plurality of second conductive lines.

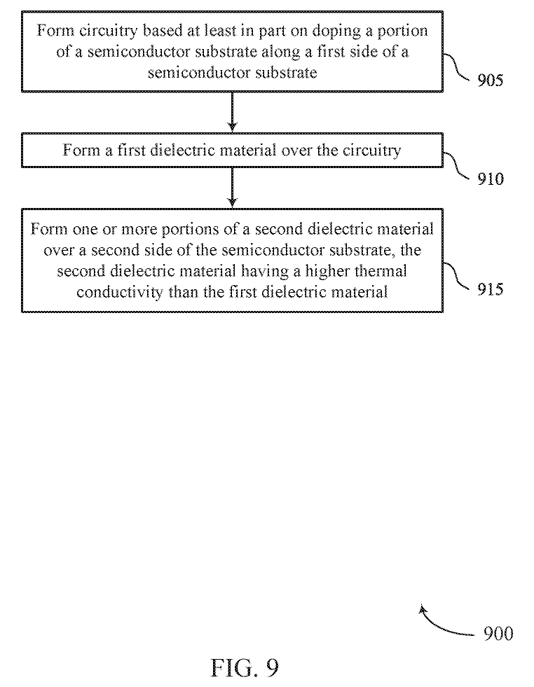

FIG. 9 shows a flowchart illustrating a method 900 that supports heat transfer structures for semiconductor apparatuses in accordance with examples as disclosed herein. The operations of method 900 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 905, the method may include forming circuitry based at least in part on doping a portion of a semiconductor substrate (e.g., a substrate 310) along a first side (e.g., a front side) of a semiconductor substrate.

At 910, the method may include forming a first dielectric material (e.g., a dielectric material 304) over the circuitry.

At 915, the method may include forming one or more portions (e.g., portions 345) of a second dielectric material (e.g., a material 306) over a second side (e.g., a back side) of the semiconductor substrate, the second dielectric material having a higher thermal conductivity than the first dielectric material.

In some examples, an apparatus (e.g., a manufacturing system) as described herein may perform a method or methods, such as the method 900. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 12: A method or apparatus including operations, features, circuitry, logic, means, or instructions, or any combination thereof for forming circuitry based at least in part on doping a portion of a semiconductor substrate along a first side of a semiconductor substrate; forming a first dielectric material over the circuitry; and forming one or more portions of a second dielectric material over a second side of the semiconductor substrate, the second dielectric material having a higher thermal conductivity than the first dielectric material.

Aspect 13: The method or apparatus of aspect 12, further including operations, features, circuitry, logic, means, or instructions, or any combination thereof for forming one or more conductive vias electrically coupled with the circuitry, the one or more conductive vias formed through the semiconductor substrate and through one of the one or more portions of the second dielectric material.

It should be noted that the aspects described herein describe possible implementations, and that the operations and the steps may be rearranged or otherwise modified and that other implementations are possible. Further, portions from two or more of the methods may be combined.

An apparatus (e.g., a semiconductor apparatus) is described. The following provides an overview of aspects of the apparatus as described herein:

Aspect 14: A semiconductor apparatus, including: a semiconductor substrate; a first interconnection layer including a plurality of first conductive lines extending over the semiconductor substrate; a second interconnection layer, between the first interconnection layer and the semiconductor substrate, including a plurality of second conductive lines extending over the semiconductor substrate; and an isolation layer, between the first interconnection layer and the second interconnection layer, including one or more portions of a first dielectric material extending through a second dielectric material that has a lower thermal conductivity than the first dielectric material.

Aspect 15: The semiconductor apparatus of aspect 14, where at least one of the one or more portions of the first dielectric material extends from a surface of one or more of the plurality of first conductive lines, from a surface of one or more of the plurality of second conductive lines, or both.

Aspect 16: The semiconductor apparatus of aspect 15, where the one or more of the plurality of first conductive lines, the one or more of the plurality of second conductive lines, or both include a conductive barrier material over a second conductive material, the at least one of the one or more portions of the first dielectric material extends from a surface of the conductive barrier material.

Aspect 17: The semiconductor apparatus of any of aspects 14 through 16, where at least one of the one or more portions of the first dielectric material, when viewed along a direction from the semiconductor substrate, is overlapping with a respective set of multiple first conductive lines of the plurality of first conductive lines, with a respective set of multiple second conductive lines of the plurality of second conductive lines, or both.

Aspect 18: The semiconductor apparatus of any of aspects 14 through 17, further including: circuitry formed at least in part from a doped portion of the semiconductor substrate and electrically coupled with the plurality of first conductive lines and the plurality of second conductive lines, where the second interconnection layer is along a same side of the semiconductor substrate as the doped portion of the semiconductor substrate.

Aspect 19: The semiconductor apparatus of any of aspects 14 through 18, where: the first dielectric material includes AlN; and the second dielectric material includes SiO.

An apparatus (e.g., a semiconductor apparatus) is described. The following provides an overview of aspects of the apparatus as described herein:

Aspect 20: A semiconductor apparatus, including: a semiconductor substrate; a first interconnection layer including a plurality of first conductive lines extending over the semiconductor substrate; a second interconnection layer, between the first interconnection layer and the semiconductor substrate, including a plurality of second conductive lines extending over the semiconductor substrate; an isolation layer between the first interconnection layer and the second interconnection layer, the isolation layer including a first layer of a first dielectric material and a second layer of a second dielectric material between the first layer of the first dielectric material and the second interconnection layer; and one or more conductor portions each extending from the second interconnection layer through the second layer of the second dielectric material and to a surface of the first dielectric material.

Aspect 21: The semiconductor apparatus of aspect 20, where at least one of the one or more conductor portions extends from a surface of one or more of the plurality of second conductive lines.

Aspect 22: The semiconductor apparatus of any of aspects 20 through 21, where at least one of the one or more conductor portions includes: a first conductive material; and a second conductive barrier material between the first conductive material and one or more of the plurality of second conductive lines and in contact with a surface of the one or more of the plurality of second conductive lines.

Aspect 23: The semiconductor apparatus of any of aspects 20 through 22, where at least one of the one or more conductor portions, when viewed along a direction from the semiconductor substrate, is overlapping with a respective set of multiple first conductive lines of the plurality of first conductive lines, with a respective set of multiple second conductive lines of the plurality of second conductive lines, or both.

Aspect 24: The semiconductor apparatus of any of aspects 20 through 23, further including: circuitry formed at least in part from a doped portion of the semiconductor substrate and electrically coupled with the plurality of first conductive lines and the plurality of second conductive lines, where the second interconnection layer is along a same side of the semiconductor substrate as the doped portion of the semiconductor substrate.

An apparatus (e.g., a semiconductor apparatus) is described. The following provides an overview of aspects of the apparatus as described herein:

Aspect 25: A semiconductor apparatus, including: a semiconductor substrate; circuitry formed at least in part from a doped portion of a front side of the semiconductor substrate; a first dielectric material formed over the circuitry on the front side of the semiconductor substrate; and one or more portions of a second dielectric material formed on a backside of the semiconductor substrate, the second dielectric material having a higher thermal conductivity than the first dielectric material.

Aspect 26: The semiconductor apparatus of aspect 25, further including: one or more vias each formed through the semiconductor substrate and through one of the one or more portions of the second dielectric material.

Aspect 27: The semiconductor apparatus of aspect 26, further including: one or more conductive pads each in contact with a respective one of the one or more vias and in contact with a corresponding one of the one or more portions of the second dielectric material.

Aspect 28: The semiconductor apparatus of any of aspects 25 through 27, further including: a layer formed over the one or more portions of the second dielectric material on the backside of the semiconductor substrate, the layer including one or more conductive portions extending through one or more second portions of the first dielectric material.

Aspect 29: The semiconductor apparatus of aspect 28, where at least one of the one or more conductive portions is formed over a respective one of the one or more portions of the second dielectric material.

Aspect 30: The semiconductor apparatus of any of aspects 25 through 29, where: the first dielectric material includes SiO; and the second dielectric material includes AlN.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor apparatus, comprising:
a semiconductor substrate;
a first interconnection layer comprising a plurality of first conductive lines extending over the semiconductor substrate;
a second interconnection layer, between the first interconnection layer and the semiconductor substrate, comprising a plurality of second conductive lines extending over the semiconductor substrate; and
an isolation layer, between the first interconnection layer and the second interconnection layer, comprising one or more portions of a first dielectric material extending through a second dielectric material that has a lower thermal conductivity than the first dielectric material.

2. The semiconductor apparatus of claim 1, wherein at least one of the one or more portions of the first dielectric material extends from a surface of one or more of the plurality of first conductive lines, from a surface of one or more of the plurality of second conductive lines, or both.

3. The semiconductor apparatus of claim 2, wherein:
the one or more of the plurality of first conductive lines, the one or more of the plurality of second conductive lines, or both comprise a conductive barrier material over a second conductive material, and
the at least one of the one or more portions of the first dielectric material extends from a surface of the conductive barrier material.

4. The semiconductor apparatus of claim 1, wherein at least one of the one or more portions of the first dielectric material, when viewed along a direction from the semiconductor substrate, is overlapping with a respective set of multiple first conductive lines of the plurality of first conductive lines, with a respective set of multiple second conductive lines of the plurality of second conductive lines, or both.

5. The semiconductor apparatus of claim 1, further comprising:
circuitry formed at least in part from a doped portion of the semiconductor substrate and electrically coupled with the plurality of first conductive lines and the plurality of second conductive lines, wherein the second interconnection layer is along a same side of the semiconductor substrate as the doped portion of the semiconductor substrate.

6. The semiconductor apparatus of claim 1, wherein:
the first dielectric material comprises aluminum nitride; and
the second dielectric material comprises silicon oxide.

7. A semiconductor apparatus, comprising:
a semiconductor substrate;
a first interconnection layer comprising a plurality of first conductive lines extending over the semiconductor substrate;
a second interconnection layer, between the first interconnection layer and the semiconductor substrate, comprising a plurality of second conductive lines extending over the semiconductor substrate;
an isolation layer between the first interconnection layer and the second interconnection layer, the isolation layer comprising a first layer of a first dielectric material and a second layer of a second dielectric material between the first layer of the first dielectric material and the second interconnection layer; and
one or more conductor portions each extending from the second interconnection layer through the second layer of the second dielectric material and to a surface of the first dielectric material.

8. The semiconductor apparatus of claim 7, wherein at least one of the one or more conductor portions extends from a surface of one or more of the plurality of second conductive lines.

9. The semiconductor apparatus of claim 7, wherein at least one of the one or more conductor portions comprises:
a first conductive material; and
a second conductive barrier material between the first conductive material and one or more of the plurality of second conductive lines and in contact with a surface of the one or more of the plurality of second conductive lines.

10. The semiconductor apparatus of claim 7, wherein at least one of the one or more conductor portions, when viewed along a direction from the semiconductor substrate, is overlapping with a respective set of multiple first conductive lines of the plurality of first conductive lines, with a respective set of multiple second conductive lines of the plurality of second conductive lines, or both.

11. The semiconductor apparatus of claim 7, further comprising:
circuitry formed at least in part from a doped portion of the semiconductor substrate and electrically coupled with the plurality of first conductive lines and the plurality of second conductive lines, wherein the second interconnection layer is along a same side of the semiconductor substrate as the doped portion of the semiconductor substrate.

12. A semiconductor apparatus, comprising:
a semiconductor substrate;
circuitry formed at least in part from a doped portion of a front side of the semiconductor substrate;
a first dielectric material formed over the circuitry on the front side of the semiconductor substrate; and
one or more portions of a second dielectric material formed on a backside of the semiconductor substrate, the second dielectric material having a higher thermal conductivity than the first dielectric material.

13. The semiconductor apparatus of claim 12, further comprising:
one or more vias each formed through the semiconductor substrate and through one of the one or more portions of the second dielectric material.

14. The semiconductor apparatus of claim 13, further comprising:
one or more conductive pads each in contact with a respective one of the one or more vias and in contact with a corresponding one of the one or more portions of the second dielectric material.

15. The semiconductor apparatus of claim 12, further comprising:
a layer formed over the one or more portions of the second dielectric material on the backside of the semiconductor substrate, the layer comprising one or more conductive portions extending through one or more second portions of the first dielectric material.

16. The semiconductor apparatus of claim 15, wherein at least one of the one or more conductive portions is formed over a respective one of the one or more portions of the second dielectric material.

17. The semiconductor apparatus of claim 12, wherein:
the first dielectric material comprises silicon oxide; and
the second dielectric material comprises aluminum nitride.

18. A method, comprising:
forming a first interconnection layer over a semiconductor substrate, the first interconnection layer comprising a plurality of first conductive lines extending over the semiconductor substrate;
forming an isolation layer over the first interconnection layer, the isolation layer comprising one or more portions of a first dielectric material extending through a second dielectric material, the second dielectric material having a higher thermal conductivity than the first dielectric material; and
forming a second interconnection layer over the isolation layer, the second interconnection layer comprising a plurality of second conductive lines extending over the semiconductor substrate.

19. The method of claim 18, wherein at least one of the one or more portions of the first dielectric material extends from a surface of one or more of the plurality of first conductive lines, from a surface of one or more of the plurality of second conductive lines, or both.

20. The method of claim 19, wherein:
the one or more of the plurality of first conductive lines, the one or more of the plurality of second conductive lines, or both comprise a conductive barrier material over a second conductive material, and
the at least one of the one or more portions of the first dielectric material extends from a surface of the conductive barrier material.

21. The method of claim 18, wherein at least one of the one or more portions of the first dielectric material, when viewed along a direction from the semiconductor substrate, is overlapping with a respective set of multiple first conductive lines of the plurality of first conductive lines, with a respective set of multiple second conductive lines of the plurality of second conductive lines, or both.

22. The method of claim 18, further comprising:
forming circuitry based at least in part on doping a portion of the semiconductor substrate, wherein the circuitry is electrically coupled with the plurality of first conductive lines and the plurality of second conductive lines, and wherein the first interconnection layer is along a same side of the semiconductor substrate as the doped portion of the semiconductor substrate.

23. The method of claim 18, wherein forming the isolation layer comprising the one or more portions of the first dielectric material comprises:
forming a layer of the second dielectric material over the first interconnection layer;
forming one or more cavities in the layer of the second dielectric material; and
forming the one or more portions of the first dielectric material in the one or more cavities.

24. The method of claim 18, wherein:
the first dielectric material comprises aluminum nitride; and
the second dielectric material comprises silicon oxide.

25. A method, comprising:
forming a first interconnection layer over a semiconductor substrate, the first interconnection layer comprising a plurality of first conductive lines extending over the semiconductor substrate;
forming a first layer of a first dielectric material over the first interconnection layer;
forming one or more cavities through the first layer of the first dielectric material and each exposing a respective one of the plurality of first conductive lines;
forming a respective conductor portion in each of the one or more cavities;
forming a second layer of a second dielectric material over the first layer of the first dielectric material and over the respective conductor portions; and
forming a second interconnection layer over the second layer of the second dielectric material, the second interconnection layer comprising a plurality of second conductive lines extending over the semiconductor substrate and separated from the respective conductor portions by the second layer of the second dielectric material.

26. The method of claim 25, further comprising:
forming a plurality of second conductor portions, each electrically coupling a respective one of the plurality of second conductive lines with a respective one of the plurality of first conductive lines through the second layer of the second dielectric material and through the first layer of the first dielectric material, and each formed continuously with the respective one of the plurality of second conductive lines.

27. The method of claim 25, wherein forming the respective conductor portion:
forming a conductive barrier material along a sidewall of a respective cavity and in contact with the respective one of the plurality of first conductive lines; and
forming a second conductive material over the conductive barrier material.

28. The method of claim 25, wherein at least one of the respective conductor portions, when viewed along a direction from the semiconductor substrate, is overlapping with a respective set of multiple second conductive lines of the plurality of second conductive lines.
